(19) United States
(12) Patent Application Publication
(10) Pub. No.: US 2016/0304352 A1
(43) Pub. Date: Oct. 20, 2016

(54) GRAPHENE TAPE

(71) Applicant: NATIONAL UNIVERSITY OF SINGAPORE, Singapore (SG)

(72) Inventors: Barbaros Ozyilmaz, Singapore (SG); Martin Fernandez, Singapore (SG); Eeshan Sandeep Kulkarni, Singapore (SG); Antonio Helio Castro Neto, Singapore (SG)

(21) Appl. No.: 15/101,121

(22) PCT Filed: Dec. 5, 2014
(86) PCT No.: PCT/SG2014/000580

§ 371 Date: Jun. 2, 2016

Related U.S. Application Data
(60) Provisional application No. 61/912,149, filed on Dec. 5, 2013.

(51) Int. Cl. C01B 31/04; B32B 37/14; B05D 1/18; B05D 1/00; B05D 1/02; C23C 16/50; B32B 43/00

(52) U.S. Cl. CPC C01B 31/0453; C23C 16/50; B32B 37/14; B32B 43/006; B05D 1/005; B05D 1/02; B05D 1/18

(57) ABSTRACT

The invention relates to a graphene tape. In particular, it relates to the manufacture, the application and possible uses of such a graphene tape. A graphene tape comprising (a) a support layer; and (b) a first nano-composite layer, the nanocomposite layer comprising a thin film layer and a graphene layer, wherein the thin film layer is disposed between the support layer and the graphene layer. A method of manufacture comprising (a) providing a substrate; (b) forming a graphene layer on the substrate; (c) depositing a thin film layer on the graphene layer; (d) applying a supporting layer on the thin film layer; (e) removing the substrate; and (f) applying a protective layer in place of the substrate.

### FIELD OF THE INVENTION

The invention relates to a graphene tape. In particular, it relates to the manufacture, the application and possible uses of such a graphene tape.

### BACKGROUND OF THE INVENTION

Researchers are demonstrating that 2D, 1D and 0D materials (known as nanomaterials) can be attractive for device applications since they may improve the characteristics and/or confer novel characteristics to such devices. They confer properties that may make them attractive both for the improvement of current applications and the development of novel applications. However, methods for the mass production of these materials are yet to be properly developed, particularly when it comes to deviation from the traditional transfer and fabrication process.

Since the synthesis of these materials is normally not optimal or compatible with the device substrate, they will have to be transferred from their growth surface and deposited on the surface. These processes will rely on the use of sacrificial layers that are initially deposited on the nanomaterials and are later removed once the transfer process is completed. Typically, polymers such as poly(methyl methacrylate) (PMMA) or polydimethylsiloxane (PDMS) have been used since they are commonly used in micro and nanofabrication processing. The use of these sacrificial layers during the transfer processes will normally result in the degradation of the nanomaterials in the form of (chemical) contamination and/or mechanical damage. Also, after the transfer, this poor quality graphene is further processed in order to pattern graphene layouts, to define electrical contacts and/or to prevent it from additional chemical and/or chemical degradation.

### SUMMARY OF THE INVENTION

In a first aspect of the present invention, there is provided a graphene tape suitable for applying on a target surface, the tape comprising: (a) a support layer; and (b) a first nanocomposite layer, the nanocomposite layer comprising a thin film layer and a graphene layer, wherein the thin film layer is disposed between the support layer and the graphene layer.

Preferably, the thin film layer is a non-sacrificial thin film layer. More preferably, the thin film layer is adapted to provide a functionality to the graphene layer.

Preferably, the thin film layer is a polymer. More preferably, the thin film layer is any one selected from the group comprising: polymethyl methacrylate (PMMA), polyvinylidene fluoride (PVDF) and its copolymers (e.g. polyvinylidene fluoride-co-trifluoroethylene (P(VDF-TrFE)), poly(3-hexylthiophene) (P3HT) and polylactide (PLA).

Preferably, the graphene layer is a matrix of graphene embedded in a thin film.

Preferably, the graphene tape further comprising a second nanocomposite layer disposed on the support layer on a surface opposite the first nanocomposite layer.

Preferably, the nanocomposite layer comprising a plurality of alternating thin film layers and graphene layers.

Preferably, the graphene tape further comprising an adhesive layer disposed between the support layer and the nanocomposite layer, wherein the thin film layer is disposed between the adhesive layer and the graphene layer.

Preferably, the graphene tape further comprising a first protector layer disposed on the support layer on a surface opposite the nanocomposite layer. In addition, the graphene tape may further comprise a second protector layer disposed on the nanocomposite layer on a surface opposite the support layer.

Preferably, the graphene layer is patterned. By “patterned”, it is meant to also include any modification and/or functionalization. The graphene layer may be functionalised according to the description of graphene. The thin film layer may also be modified but this could be considered part of the thin film deposition process which will be described in detail later.

Preferably, the target surface is any one selected from the group comprising: silicon wafers, glass, quartz, mica, polyethylene terephthalate (PET), polyimide foils and paper, and any other surface that has been prepared on such substrates.

In a second aspect of the present invention, there is provided a method of forming a graphene tape, the method comprising: (a) providing a substrate; (b) forming a graphene layer on the substrate; (c) depositing a thin film layer on the graphene layer; (d) applying a supporting layer on the thin film layer; (e) removing the substrate

Preferably, the method further comprising the step of applying a protector layer in place of the substrate.

Preferably, the thin film layer is a non-sacrificial thin film layer.

Preferably, the thin film layer is adapted to provide a functionality to the graphene layer.

Preferably, the method further comprising cleaning the graphene layer prior to depositing a thin film layer on the graphene layer.

Preferably, the step of depositing the thin film layer on the graphene layer is any one selected from the group comprising: bar-coating, spin coating, spray coating, polymer evaporation, Langmuir-Blodgett deposition, dip coating, doctor blade, slot-die coating, film lamination and direct deposition from melt.

Preferably, the step of applying the supporting layer on the thin film layer is by any one from selected group comprising: electrostatic transfer and processes involving applying pressure such as, rolling, laminating, hot-pressing or autoclave processing.

Preferably, the step of removing the substrate is any one selected from the group comprising: chemical removal, electrostatic transfer and chemical delamination.

Preferably, the steps (b) and (c) are repeated after step (e) to obtain multiple layers of thin films and graphene layers.

Preferably, the method further comprising patterning the graphene and thin film layers.

Preferably, the thin film layer is a polymer and is any one selected from the group comprising: polymethyl methacrylate (PMMA), polyvinylidene fluoride (PVDF) and its copolymers (e.g. polyvinylidene fluoride-co-trifluoroethylene (P(VDF-TrFE)), poly(3-hexylthiophene) (P3HT) and polylactide (PLA).

Preferably, the substrate is a metal substrate. More preferably, the metal substrate is copper.

Preferably, the protector layer is a self-release layer.

In another aspect of the present invention, there is provided a product comprising a graphene tape according to the first aspect of the invention. In a further aspect of the present invention, there is also provided a method of forming a product comprising applying the graphene tape according to the first aspect of the invention onto a surface of the product.

This disclosure relates to the development of a graphene tape, in order to apply such material to any given target surface. This tape can solve existing issues that make it difficult for the large area application of graphene in different configurations. Applications of the graphene tape range from the application of a single layer of graphene or the application of semi- of fully operative graphene devices (in the case where the graphene layer has been pre-patterned during the fabrication of the graphene tape) onto a given surface for the fabrication of graphene containing electronic-like devices, to other lower end applications intended to quickly form electrical and thermal connections between two or more surfaces.

The graphene tapes can be used for the large-area application of graphene on a surface.

The tape is compatible with the application of graphene to substrates such as silicon wafers, glass, quartz, mica, polyethylene terephthalate (PET) or polyimide foils and paper, any other surface that has been prepared on such substrates or any other flat surface. The graphene tape may be used in applications such as the large scale fabrication of graphene devices, device encapsulation, composite materials applications based on graphene multi-stacks or for the transparent electrical and/or thermal interconnection of two surfaces. The tape may also be used in any other application where the properties of graphene and the non-sacrificial thin film layer are of interest for the experts in the field.

The graphene tapes can boost mass production of products and applications based on graphene and/or other nanomaterials, and boost device fabrication strategies based on tape application methods versus the traditional layer-by-layer ones.

Due to its exceptional mechanical, electronic, chemical, optical or thermal properties, among others, graphene has been coming under increasing interest for a wide range of applications, including electronic devices and energy storage applications. However, its industrial scale availability is generally as a powder, which form often does not lend itself to many applications. Graphene has been added to polymeric binders and other materials to form composites that be used for many applications, but the presence of the other components in the composites can adversely affect the electrical, chemical, or other desired properties of the material. It would thus be desirable to obtain a free-standing, mechanically stable graphene material containing little to no binder or other additives.

Advantageously, a preferred embodiment of this invention does not refer to blends but to continuous, residue and defect free graphene films that result from its transfer together with a non-sacrificial thin film layer that, in addition to help to the transfer yield, the non-sacrificial thin film layer also adds value to the characteristics of the graphene film. The non-sacrificial thin film will mechanically and chemically protect the graphene layer while the fabrication and application of the tape. More importantly, it is to add functionality to the nanocomposite when stacked with the graphene. Because of this added functionality, the non-sacrificial thin film is not to be removed once the nanocomposite is applied, it is non-sacrificial, and, therefore, it will not cause mechanical damage and/or contaminate the graphene layer as when a sacrificial layer is used to transfer graphene. Hence, advantageously, the graphene material of the present invention is free of defects or residues.

### BRIEF DESCRIPTION OF THE FIGURES

In order that the present invention may be fully understood and readily put into practical effect, there shall now be described by way of non-limitative examples only preferred embodiments of the present invention, the description being with reference to the accompanying illustrative figures.

In the Figures:

FIG. 1 is a schematic diagram showing the graphene tape according to an embodiment of the present invention;

FIGS. 2(a) and (b) are schematic diagrams showing the graphene tape according to another embodiment of the present invention;

FIGS. 3(a) to (e) are schematic diagrams showing various structure configurations of the graphene/nanomaterial film according to an embodiment of the present invention;

FIGS. 4(a) to (d) are schematic diagrams showing patterning of the graphene/nanomaterial film according to an embodiment of the present invention;

FIGS. 5(a) to (d) are flow charts showing the fabrication of the graphene tape according to an embodiment of the present invention;

FIG. 6 is an optical picture of a graphene tape according to an embodiment of the present invention;

FIGS. 7(a) and (b) are optical pictures of the nanocomposite film on (a) rigid and (b) flexible substrates after fabrication and application of the graphene tape according to two different embodiments of the current invention; and

FIGS. 8(a) and (b) are respectively, an optical picture of a graphene layer after application of a graphene tape according to one of the embodiments of the present invention and the statistical analysis on the continuity of the graphene layer.

### DETAILED DESCRIPTION OF THE PREFERRED EMBODIMENTS

Structure of the Tape

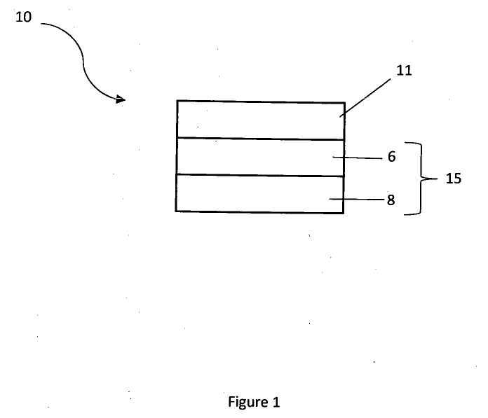

FIG. 1 shows a basic structure of the graphene tape according to any embodiment of the present invention.

In its basic form, there is provided a graphene tape (10) having a support layer (11) and a nanocomposite layer (15) formed on the support layer (11). The nanocomposite layer (15) itself includes a thin film layer (6) and a graphene layer (8). From FIG. 1, it can be seen that the thin film layer (6) is disposed between the support layer (11) and the graphene layer (8), i.e. it separates the support layer (11) and the graphene layer (8). The support layer (11) may be any support foil that provides the necessary mechanical support for the nanocomposite layer (15).

Hereon and unless otherwise stated, the terms surface or device surface will both refer to the target surface the graphene tape is to be applied to.

The present invention relates to the use of a graphene layer in the manufacture of a graphene tape. The graphene layer may be continuous, transparent and/or one atom thick. By “graphene layer”, it is meant a layer containing graphene. Graphene is a 2D sp2-hybridized carbon sheet with one-atom thickness that absorbs 2.3% of the in the optical spectrum. Because of its unique structure and special properties, graphene has attracted increasing attention in recent years. Its high theoretical surface area (2630 m²g⁻¹), chemically stability and high electrical conductivity make it an attractive material for applications in nanoelectronics, optoelectronics, energy-storage systems and chemical sensors.

Further, the term “graphene” includes any graphitic carbon material such as, but not limited to, single layer graphene and multilayer graphene (up to 100 layers) single-wall and multi-walled carbon nanotubes and their composites, including any modifications and/or functionalisations. Hereon and unless otherwise stated, graphene will also apply to any other 2D-like nanomaterial in any of their structures or arrangements, such as molybdenum disulphide or black phosphorus.

By “thin film layer”, it is meant to include any structural material that may support the graphene layer and add functionality to the graphene. Examples of functionality include doping the graphene, protecting the graphene and providing biodegradable characteristics to the graphene.

Further, in a preferred embodiment, the thin film layer (6) is non-sacrificial. As such, any reference made to the thin film layer of the present invention includes a reference to a non-sacrificial thin film layer. The non-sacrificial thin film layer results in an improved or added functionality of the graphene tape. By “non-sacrificial”, it is meant that the thin film is not a layer that is only to be deposited to assist in the fabrication and application of the graphene layer and is later to be removed, but that it is to remain together with the graphene layer after application of the tape, to a target surface. Partial post-patterning of the thin film, different from removal, may be required for post-patterning of a graphene device. As such, the nanocomposite layer (15) includes both a graphene layer (8) and a non-sacrificial thin film layer (6). The nanocomposite layer (15) may comprise graphene or functionalised or modified graphene attached to the non-sacrificial thin film layer. In an embodiment of the present invention, the non-sacrificial thin film layer may be a polymer. By “polymer”, it is meant to refer to any large molecule or macromolecule structure that is made up of many repeated subunits. Alternatively, the polymer layer may not be a polymer but any non-sacrificial thin film material that will give mechanical stability to the nanocomposite layer and that could result in providing attractive properties to the graphene layer. Examples of possible non-sacrificial thin films, but not limited to this list, are polymethyl methacrylate (PMMA), polyvinylidene fluoride (PVDF) and its copolymers; poly(3-hexylthiophene) (P3HT) or polylactide (PLA).

By “support layer”, it is meant the base film that supports or carries the nanocomposite film (15). The support layer (11) can be composed of materials such as, but no limited to, polyester, polyimide, vinyl, Polyethylene terephthalate (PET) or Teflon.

The support layer (11) may have a protector layer (14) on its other exposed surface—the surface opposite to the nanocomposite layer (15). Likewise, the nanocomposite layer may also have a protector layer (13) on its other exposed surface—the surface opposite the support layer (11). In an embodiment of the invention, an adhesive layer (12) disposed between the support layer (11) and the nanocomposite layer (15)—the polymer layer (6) is disposed between the adhesive layer (12) and the graphene layer (8).

FIG. 1 is the most generic structure of the tape. It refers to a graphene tape having one graphene layer, for example a single layer graphene (SLG). In another embodiment of the invention, the graphene tape may comprise a multi-stacked nanocomposite layer (15). The nanocomposite layer (15) may have a plurality of non-sacrificial thin film layers (6), which are also known as polymer layers, and graphene layers (8). Within the nanocomposite layer (15), there could also be just one non-sacrificial thin film layer (6) and a plurality of graphene layers (8) stacked together. The only requirement is that there must be at least one non-sacrificial thin film layer (6) for separating the support layer (11) from the graphene layer (8). These will be described in detail below.

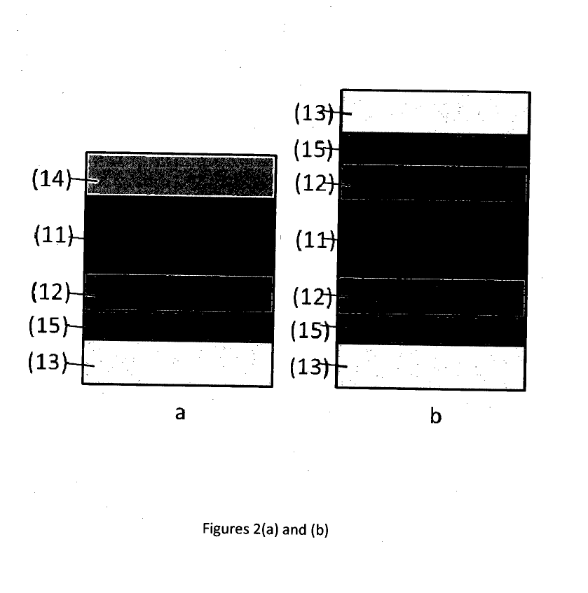

FIG. 2(a) shows a further example of the generic structure of a graphene tape having a graphene layer on one side of the tape. As in the graphene tape (10) shown in FIG. 1, the graphene tape shown in FIG. 2(a) is necessarily formed of a support foil (11) and a nanocomposite layer (15) which is made up of the non-sacrificial thin film layer and the graphene layer. The tape may include an adhesive layer (12) between the support foil and the nanocomposite layer (15). The tape may also include a self-release protector (13) to protect the nanocomposite layer (15) from degradation before the tape is applied to the target substrate. The tape could also include a self-release protector (14) to protect the support foil (11) during the fabrication of the tape and its application' to the target substrate. The support foil (11), the adhesive (12) and protection layer (14) may also collectively be referred to as the support layer.

An example of the generic structure of a double-sided graphene tape is shown in FIG. 2(b). This tape includes a support layer/foil (11) and two nanocomposite layers (15). As can be seen in FIG. 2(b), the nanocomposite layers (15) are formed on opposite sides of the support layer (11). The tape may also be formed of the adhesive layers (12) and the protective self-release layers (13).

The exact materials to form the support (11, 12, 14) and the nanocomposite layer (15) are to be chosen to match the requirements of the application the tape targets. For example, if the support is to delaminate from the nanocomposite layer (15) once the tape has been applied, these materials are to be chosen accordingly. For example, if the polymer (6) forming the nanocomposite layer (15) is to be an active layer of the final device, it will be chosen so that it will enhance and/or complement the characteristics of the graphene in the device application.

Structure of the Nanocomposite Layer

In every graphene tape configuration, the graphene layer (8) will always be separated from the support layer (11) by the non-sacrificial thin film layer (6).

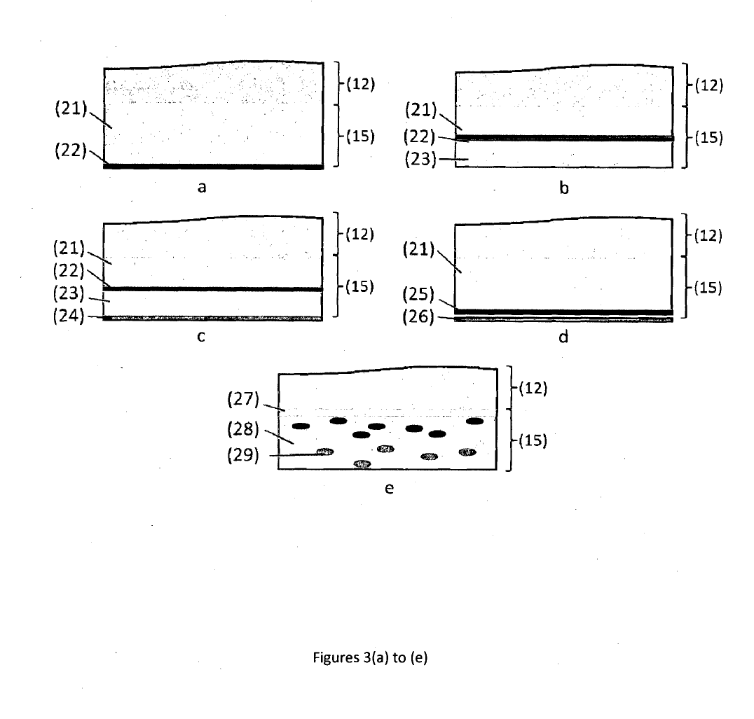

The most basic structure of the nanocomposite layer (15) is composed of a graphene layer (22) and a non-sacrificial thin film layer (21) as shown in FIG. 3(a). The nanocomposite layer (15) may also be fabricated to match other structures such as those shown in FIGS. 3(b) to (e). The following describes these various embodiments of the present invention.

FIG. 3(b) shows a nanocomposite layer (15) that may be composed of a non-sacrificial thin film layer (21), graphene layer (22) and non-sacrificial thin film layer (23) multi-stack.

FIG. 3(c) shows a nanocomposite layer (15) that is composed of multi-stack of non-sacrificial thin film layer (21)/graphene layer (22) and a further non-sacrificial thin film layer (23)/graphene layer (24).

FIG. 3(d) shows a nanocomposite layer (15) that is composed of a non-sacrificial thin film layer (21), and a stack of more than one graphene layers (25, 26) in a multi-stack structure.

In a further embodiment of the invention, which will be described in detail below, the graphene layer may be a matrix of graphene embedded in a non-sacrificial thin film layer, for example a polymer. The graphene/polymer matrix (8) is separated from the support layer (11) by the non-sacrificial thin film polymer layer (6). This is shown in FIG. 3(e). FIG. 3(e) shows the most general nanocomposite layer (15) structure where the graphene layers (8, 29) are embedded in a non-sacrificial thin film layer matrix (28), the only requirement being that the interaction with the support layer (11) is with an only non-sacrificial thin film layer (6, 27).

The key benefits of the graphene tape is related to the graphene in combination with the non-sacrificial thin film layer (6) ((21) in the case of FIG. 3(a)) in between the support layer (11) and the graphene layer (8) ((22) in the case of FIG. 3(a)).

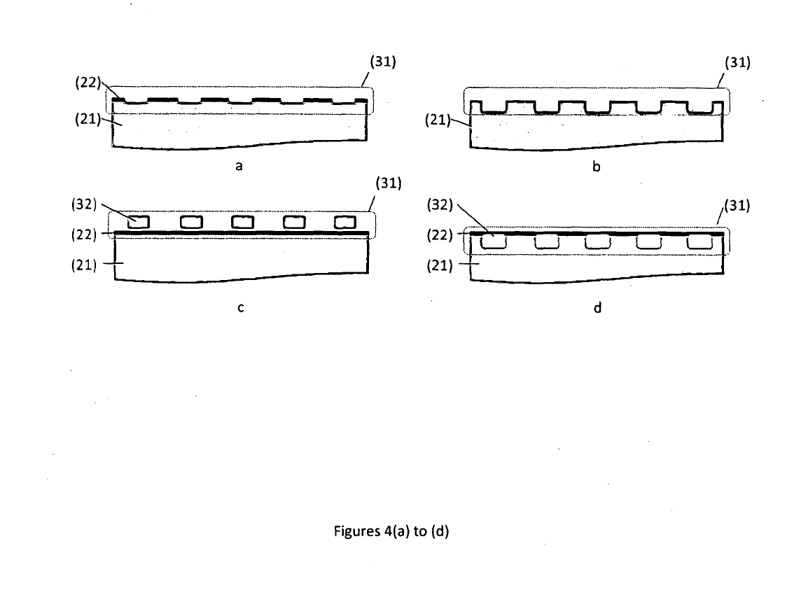

The structure of the nanocomposite layer (15) can be modified by prepatterning or etching of the nanocomposite layer prior to the layer stacking, and/or by deposition of motifs at any of the graphene layer or non-sacrificial thin film layer interfaces as shown in the schematics in FIG. 4 or any of their combinations. For example, these patterning can enable alignment of the nanocomposite layer with any level that had been previously patterned or that is to be patterned afterwards. Thus, the tape enables the direct printing of a graphene device component, even the print of full operative graphene devices.

FIG. 4(a) shows the patterning (31) of the graphene layer (22). FIG. 4(b) shows patterning (31) of the non-sacrificial thin film layer (21). FIG. 4(c) shows material deposition (32) on the external interface of the graphene layer (22). FIG. 4(d) shows material deposition (32) at the graphene layer-non-sacrificial thin film layer interface (21/22).

Fabrication of the Graphene Tape

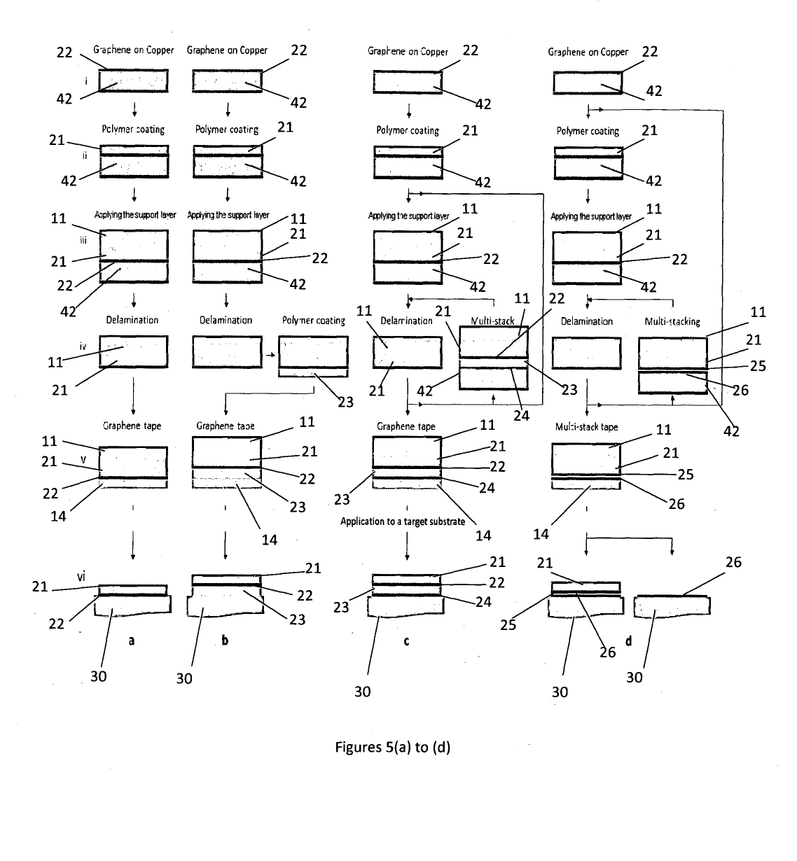

FIG. 5(a) shows a possible cycle diagram for the fabrication of a graphene tape (10) according to an embodiment of the present invention to fabricate a graphene tape (10) having a nanocomposite layer (15) as shown in FIG. 2(a). FIG. 5(a) results in a graphene tape (10) having the basic structure layer, in sequence: a support layer (11), a non-sacrificial thin film (polymer) layer (21), a graphene layer (22), and a protector layer (14).

Optimal starting material is the substrate (42) where graphene has been grown or deposited on at least one of the surfaces. In an embodiment of the present invention, the substrate (42) may be a metal. More particularly, the substrate (42) may be copper. Other metal substrates such as nickel or platinum or any other substrate know by the people skilled in the art for the preparation of a graphene layer would also be compatible with the fabrication of the tape. The growing or formation of the graphene layer (22) on the metallic substrate (42) may be carried out by any technique known to the skilled person such as but, not limited to, thermal, rapid thermal or plasma chemical vapour deposition (CVD). In the case of thermal CVD and as an example on the preparation of the graphene layer of the present invention, a mixture of a hydrocarbon, such as methane or acetylene, and hydrogen can be used as the carbon source to grow one layer of graphene on a copper substrate at about 1000° C. The growth of the graphene may be achieved over any suitable size, for example lengths in the tens of centimetre range and beyond. If copper substrate was a copper foil, the area of the graphene would be limited to the surface of the foil. Alternatively, if the copper was a thin film that had been predeposited on a substrate such as a silicon-silicon oxide wafer, the area or the graphene will be limited to the area of the wafer covered with by copper. The graphene surface can be predefined by processes such as, but not limited to, defining a mask to the growth of graphene or by selectively removing the metal surface from the wafer prior to graphene growth, for a patterned growth of the graphene layer. Alternatively, the graphene may be patterned while on the substrate before depositing the thin film layer by processes such as but not limited to laser writing, oxygen or argon plasma etching or ozone etching. Alternatively, the graphene layer may be formed on the substrate after applying the graphene from a previous substrate by a methodology such as the methods described in the embodiments of this invention or by any other means known by the experts in the field. Graphene size will only be limited by the maximum allowed sample size at the graphene growth/deposition system. Alternative to the length of the graphene tape, graphene stacking strategies may be adopted to assure continuity of the graphene tape.

Since the non-sacrificial thin film layer is to be deposited just after the formation of the graphene layer, there will not be any contamination. In some embodiments, cleaning steps are involved and these steps could include, but would not be limited to, solvent cleaning, plasma treatment and thermal annealing.

The non-sacrificial thin film layer (polymer) (21) is then deposited or coated on top of the graphene layer (22) that is to form the tape. Techniques such as bar-coating or any other process resulting in the deposition of a thin polymer layer on a surface such as, but not limited to, spin coating, spray coating, polymer evaporation, Langmuir-Blodgett deposition, dip coating; doctor blade, slot-die coating, film lamination or direct deposition from melt, may be used to complete this step. Typically, the thickness of the non-sacrificial thin film layer ranges from 0.1 nanometers to 5 micrometers. Further post-processing of the non-sacrificial thin film layer such as, but not limited to, annealing for solvent evaporation, or to promote crystallization of the non-sacrificial thin film or other processes for the functionalization/modification of the non-sacrificial thin film such as, but not limited to, applying an electric field to align the dipoles in the case of a ferroelectric thin film, or to change the contact angle of the surface of the thin film layer may be considered to be part of the deposition of the non-sacrificial thin film on the graphene layer.

Next is the application of the support layer (11) on top on the metallic substrate (42), graphene layer (22) and non-sacrificial thin film layer (21) stack by processes such as but not limited to electrostatic transfer and/or processes involving applying pressure such as, rolling, laminating, hot-pressing or autoclave processing.

Delamination of the graphene tape from the substrate (42), for example, if copper was the substrate this step could be completed by processes such as, but not limited to, chemical etching in solutions of, for example, ammonium persulfate of iron chloride, by electrochemical delamination in solutions of, for example, ammonium persulfate or sodium chloride or by electrostatic transfer.

The graphene layer could be released from other substrates too, for example SiO₂.

Finally, application of the protective self-release layer (14) and assembly of the graphene tape into a roll or into any other form of packaging in accordance with the final application of the tape is carried out.

FIG. 5(b) is a possible cycle diagram for the case where the nanocomposite layer is to be that shown in FIG. 3(b), a non-sacrificial thin film layer (21)/graphene layer (22)/non-sacrificial thin film layer (23) multi-stack film. In this case, after the tape is delaminated, a new non-sacrificial thin film layer (23) is deposited on the graphene layer (22). FIG. 5(b) results in a graphene tape (10) having the basic structure layer, in sequence: a support layer (11), a non-sacrificial thin film layer (21), a graphene layer (22), a non-sacrificial thin film layer (23) and a protector layer (14).

FIG. 5(c) is a possible cycle diagram for the case where the nanocomposite layer is to be that shown in FIG. 3(c), a non-sacrificial thin film layer (21) and a graphene layer (22) multi-stack. In this case, after the tape is delaminated from the metal substrate (step (iv) in the previous description chart), the tape is applied again onto the metal substrate/graphene layer/non-sacrificial thin film layer stack after step (ii). This is to be repeated as many times as needed until the required multi-stacking is achieved. FIG. 5(c) results in a graphene tape (10) having the basic structure layer, in sequence: a support layer (11), a non-sacrificial thin film layer (21), a graphene layer (22), a non-sacrificial thin film layer (23), a graphene layer (24) and a protector layer (14).

FIG. 5(d) is a possible cycle diagram for the case where the nanocomposite layer is to be that shown in FIG. 3(d)—the non-sacrificial thin film layer (21) and a graphene layer multi-stack (25, 26) nanocomposite layer. In this case, after the tape is delaminated (step (iv) in the previous description chart), the tape is applied again onto the starting material (i). This is to be repeated as many times as needed until the required multi-stacking is achieved. FIG. 5(d) results in a graphene tape (10) having the basic structure layer, in sequence: a support layer (11), a non-sacrificial thin film layer (21), a graphene layer (25), a graphene layer (26) and a protector layer (14). In the present case, there are two stacks of graphene layers in the nanocomposite layer.

The fabrication scheme of nanocomposite layer based on the structure in FIG. 3(e) is similar to those in FIG. 5. In this case, however, other processes will be applied for the fabrication of the non-sacrificial thin film and graphene composites and their multi-stacks. The graphene/polymer matrix may be prepared by any technique that is known to the skilled person.

In the cases where the nanocomposite layer (15) is to be patterned as shown in FIG. 4, processes such as, but not limited to contact printing or plasma etching, and screen printing, inkjet printing or spray coating could be used to etch and deposit motifs on the graphene layer interfaces, respectively.

The above process schemes are just an example of the possible graphene tape production schemes. Any other methods known to the skilled person may be used, for example as an alternative combination of the above processes and structures, starting graphenes, non-sacrificial thin film layers deposition methodologies, support foils and adhesive application, and/or tape assembly strategies.

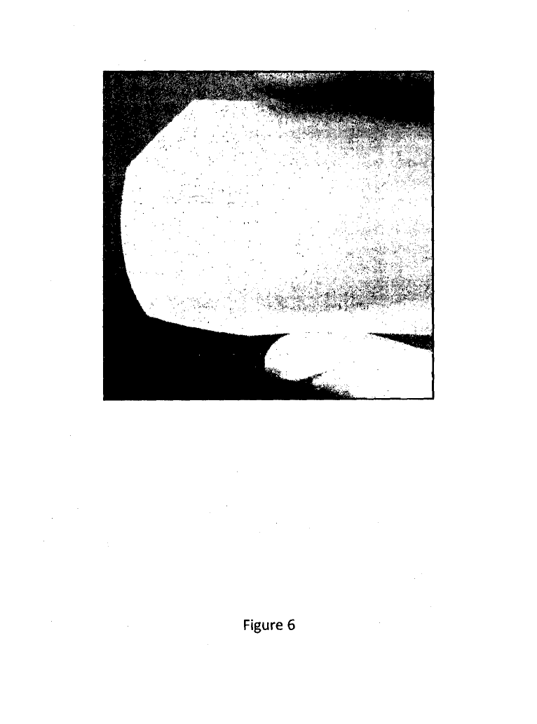

The graphene tape technology can be applied to the production of tapes for the application of any nanomaterial film and for the application of any of their multi-stack based on their combinations. In addition, the polymer layer needs not be a polymer. Any non-sacrificial thin film material that will give mechanical stability to the nanomaterials and/or that could result in enhanced characteristics for a given application when multi-stacked with them, will also be of interest. FIG. 6 shows an optical picture of a one layer graphene tape that had been fabricated and then patterned according to an embodiment of the present invention described above.

The growth of the graphene may be achieved over any suitable sample size, for example lengths in the tens of centimetre range and beyond. Graphene size will only be limited by the maximum allowed sample size at the graphene growth/deposition system. Alternative to the length of the graphene tape, graphene stacking strategies may be adopted to assure continuity. The fabrication of the tape as described in the embodiments of this invention is ideal for in-line production of the tapes.

The graphene layer may be grown on the metallic substrate as described above. As an alternative, the graphene layer be grown separately and then formed on the support layer. The following provides an example of growing the graphene layer.

Application of the Tape to a Target Surface

The application of the graphene tape to a target substrate surface (30) will normally be based on the application of pressure and/or heat. The application may be seen in step (vi) in FIGS. 5(a) to (d). Other application strategies such as, but not limited to, electrostatic transfer could also be implemented. Prior to the application of the tape the target surface may need to be cleaned to minimize the contaminants and hence, to promote a good binding. Pressure will aim at achieving a good binding of the nanocomposite layer to the destination surface. Heat will also aim at achieving a good binding between the nanocomposite layer and the substrate, but also, it could be the mechanism to delaminate the support from the nanocomposite layer (15). No residues from the support are to be left on the nanocomposite layer after delamination. The present invention may use any thermal release adhesive tape to achieve application.

Depending on the target application the tape could be applied by, but not limited to, finger pressure, with a roll, with an office laminator, by heating at a certain temperature or by industrial methods such as, roll-to-roll or hot-press at temperatures between 50° C. and 150° C.

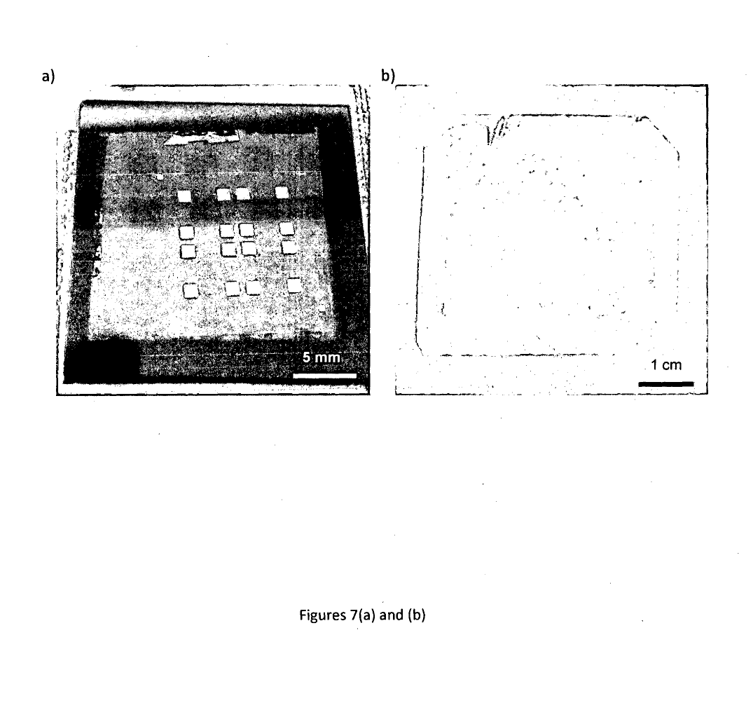

The graphene tape of the present invention may be applied to surfaces with roughness in the micrometer range and to surfaces where features had been pre-patterned. The present graphene tape has been shown to result in a good transfer to substrates that are considered by a skilled person to be rough, such as PET foils and paper. FIGS. 7(a) and (b) shows examples of nanocomposites after the application of graphene tapes onto a silicon-silicon oxide wafer (as shown in FIG. 7(a)) and a PET foil (as shown in FIG. 7(b)) according to the embodiments of the present invention. In (a) the graphene layer had been prepatterned by selectively removing part of the graphene layer and by defining metallic motifs at the graphene layer/non-sacrificial thin film layer interface according to the embodiments of the present invention. The device in (b) is an example of a non-sacrificial thin film layer and a graphene multi-layer stack that had been pre-patterned to define motifs on each of the graphene layers that were used for their alignment according to various embodiments of the present invention.

Post-Application Usage

Once the graphene has been applied to the surface, there may be post-application modification processes applied to either the non-sacrificial thin film polymer layer or to the graphene layer. These may include but are not limited to electrical polarization or annealing. Such processes may assist in improving properties of the deposited nanocomposite layer such as the electrical, mechanical or optical properties. For example, if the graphene layer is a single graphene layer and the non-sacrificial thin film layer is P(VDF-TrFE)), the dipoles forming the P(VDF-TrFE) film could be aligned by applying an electric field across the P(VDF-TrFE) film and this alignment could result in doping on the graphene layer that may improve the conducting characteristics of the nanocomposite layer.

Once the tape has been applied and any post-application are completed, the applied nanocomposite layer will be fully functional. If the applied material is to be part of a device, it could be that extra fabrication steps such as but not limited to patterning the nanocomposite or defining electrical contacts will be needed to complete the device fabrication.

Conclusion

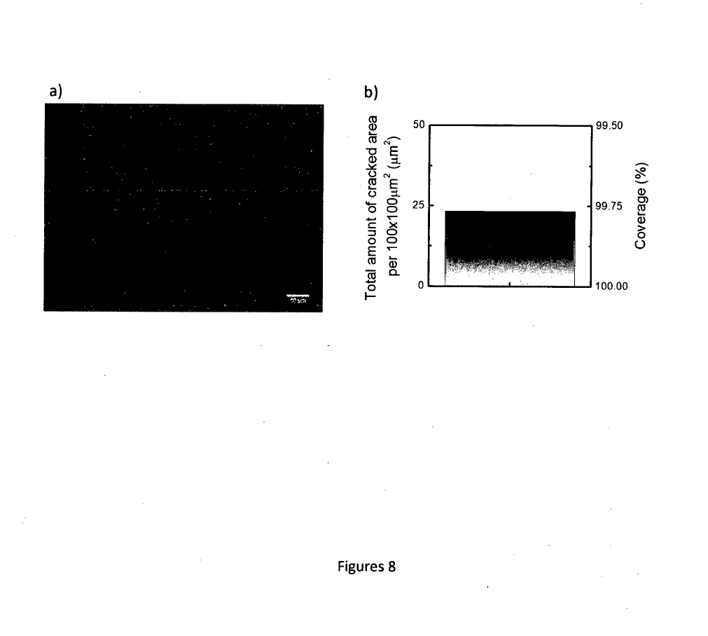

The graphene tape of the present invention overcomes the existing issues for the application of graphene to a target surface, that is, the residues and the mechanical damage occurring from the use of sacrificial transfer layers. The tape enables the application of individual single layer graphene (SLG), graphene multi-stacks and graphene-polymer heterostructures. The graphene being applied may be continuous, (for example, the graphene coverage will be equal or above 90% of the surface) and residue free at the interfaces (residues on the graphene from the tape will cover less than 10% of the graphene surface). As an example of the tape application, FIG. 8 is (a) an optical image of a graphene layer resulting from the application of a graphene tape according to the embodiments of the invention and (b) is the statistical evaluation of the continuity of such film.

There are no defects introduced to the graphene (graphene can be applied with a 90% yield in coverage with respect to the graphene coverage on the initial graphene substrate the tape is made of) because i non-sacrificial thin film layer that is different from the tape support mechanically protects the graphene during the fabrication of the tape and during its application to the target surface. Resulting from the low level of defects, inline fabrication yield of devices based on the tape will be maximized.

In the tape configuration as shown in FIG. 3(d) and in the embodiments in FIG. 5(d) where only one graphene layer (26) is applied onto the target surface (30), the graphene layer (26) will not come into contact with any non-sacrificial thin film polymer layer before it is applied to the substrate surface (except for any areas where the interlayer graphene (25) may not cover the non-sacrificial thin film (21)). Thus, the interfaces of the applied graphene will be free of residues (except for those areas resulting from the contact with the non-sacrificial thin film layer (21) through defect on the top graphene layer (25)). This transfer/application results in a contamination-free transfer of the bottom graphene layer (26).

In the tape configuration where a non-sacrificial thin film layer and graphene layer multi-stack is to be applied onto the surface (as can be seen in the graphene tape configurations shown in FIGS. 3(a) to (c)), there will not be residues from the transfer thin film layer at the graphene interface (below 5% coverage of polymer residues over the full graphene surface) because the polymer forming the tape will become an active layer of the device and, thus, it will not be a residue and will not need to be removed. The non-sacrificial thin film layer forming the tape may be selected such that it will contribute to the properties and characteristics of the nanocomposite film (for example electrical and mechanical properties). For example, if P(VDF-TrFE)) is used, it can act as the dielectric layer in transistor or memory like applications, or as the graphene doping material in graphene based electrode applications.

The fabrication of the graphene tape is compatible with a roll-to-roll production process and non-expensive materials are only needed for its manufacture. Therefore, the graphene tape is compatible with large scale production.

The graphene tape enables the large area, position controlled and residue free application of graphene to a flat target surface. This means that the tape is compatible with layer-by-layer fabrication methods and can be applied to any flat surface. Since the tape application is not solution-based, the interface between the graphene and the surface can be controlled so that it is residue free. Also, since the graphene will not become in contact with any material during the fabrication but with the non-sacrificial thin film layer, that is not to be removed and is to contribute to the functionality of the graphene nanocomposite, and with the materials used in the fabrication of the tape as described above, the interfaces of the graphene will be free from residues from polymers or other materials that are used as the transfer layer in other state of the art graphene transfer processes.

The tape also enables the large area, position controlled and residue free application of complex graphene-non-sacrificial thin film and graphene-graphene heterostructures, stacks or ply laminates with clean interfaces to a flat surface. This tape enables the mass production of graphene heterostructures and novel composite materials. Since the composition of the layers to form the nanocomposite layer can be selected, these composites can be tuned to show unique properties for a determined application. Since the non-sacrificial thin film layer is to be directly deposited on graphene (and not a result of any prior processing as may be carried out by existing fabrication processes), this interface will be free of residues and protected from contamination and mechanical damage. Again, the tape is compatible with layer-by-layer fabrication methods and can be applied to any flat surface. Since the tape application is not solution based, the interface between the graphene and the surface can be controlled so that it is residue free. The interfaces having no residues, the interaction between the graphene layer and the non-sacrificial thin film layer is optimal.

The graphene tape also enables the direct printing of functional graphene based component or even full graphene based devices on a given surface. As such, the device area will only depend on tape fabrication. The patterning of the tape enables level alignment in layer by layer fabrication of device—etching of the non-sacrificial thin film polymer layer and graphene enables graphene patterning. Further, material deposition enables the patterning of structures such as contacts. As example, single layer graphene could be coated with a thin layer of P(VDF-TrFE) and then patterned to form touch sensors, and these touch-sensors could be later printed on the glass covers or the LCD screens of touch-screen like applications.

The graphene tape also enables the application of an electrically and thermally conductive, transparent coating over any surface, or between any contacts. Graphene being transparent and electrically and thermally conductive results in the graphene tape being a transparent, current and heat conductor. Surfaces may be flexible or rigid, and the deposited graphene film will bend accordingly.

In addition to the above, the main difference of the graphene tape, and what confers its advantage over other methods, is that the non-sacrificial thin film polymer layer in between the support/adhesive layers (11, 12) is the key to the application of the tape. The non-sacrificial thin film polymer layer does not only work as a transfer layer for mechanical stability of the graphene. It is because of the non-sacrificial thin film polymer layer that the tape can result in the application of a residue free graphene or in residue free graphene/polymer interfaces. Resulting from this, the interaction of the graphene and the polymer is improved with respect to the case where a sacrificial layer is used in the application of graphene.

This results in the interfaces on the graphene or multi-stacks are residue free, thus the interfaces are better quality than after previous methods, thus, device operation is to be improved when using the graphene tape.

Also, there is no need for extra processing steps to remove any non-sacrificial thin film polymer layer or any adhesive residues. As a result, the application of the graphene or multi-stack becomes simpler and cheaper since less material and residues are to be used and to be generated during the application process.

The tape can boost the coating of surfaces with SGL, SGL multi-stacks and other 2D, 1D and 0D nanomaterials. The graphene tape could be used in, but would not be limited to, quite a number of applications.

For example, it may be used in electronics. The tape is fully compatible with roll-to-roll processing, thus it is compatible with the processing of flexible and also wafer based electronics. Since its easy application, it could have high impact at both a research and an applications level. In another example, the applied graphene may be used for the fabrication of graphene based integrated circuits. The graphene tape may be used in the application of non-sacrificial thin film layer/graphene stacks, for example, a P(VDF-TrFE)/graphene stack could be used for the fabrication of low sheet resistance electrodes for touch screen applications (i.e ITO replacement). The graphene tape simplifies the processing steps and results in more continuous graphene layers (less mechanically defective) and less contaminated (less residues) that improves the device fabrication yield and the device characteristics. For example, in the case of thin film conductors, the graphene tape in the case of a P(VDF-TrFE) non-sacrificial thin film layer would result in improved conductivity with respect to its counterpart processed with a sacrifitial layer and later coated with P(VDF-TrFE).

Patterned graphene tapes may be used for the direct printing of graphene based device components or full devices. For example, a graphene pattern could be applied to form electrical interconnects or a heat dissipation element component. For example, a single layer graphene may be coated with a thin layer of P(VDF-TrFE) and then patterned to form touch sensors, and these touch-sensors may be later printed on the glass covers or the LCD screens of touch-screen like applications.

The mechanical stability of the graphene resulting from its combination with the non-sacrificial thin film enables the application of a single layer of graphene or multi-stacks of single layer graphene to non-conventional substrates, such as paper. Thus, the fabrication of graphene devices based on SGL or their multi-stack on paper.

The graphene tape of the present invention may be used in making composite devices.

The graphene multi-stacks may be used for the fabrication of membrane-like devices, for example, for the fabrication of micro- or nanomechanical actuators. The non-sacrificial thin film layer gives mechanical stability to the graphene. Graphene would become mechanically damaged if a sacrificial layer would be used.

The graphene multi-stacks can also be used to fabricate of composites with improved mechanical properties. For example, graphene stacks could substitute glass and/or carbon fibers and improve the mechanical properties of such structures.

The multi-stacks could also be used for distributing electricity or for heat conduction and/or dissipation. As such, it can be used as a conductive wire or for a uniform spreading of heat in cooking applications. Moving further, the graphene tape may also be used for making or repairing electrical contacts either at a small scale i.e. on integrated chips, a medium scale i.e. for household repair jobs or for large scale i.e. heat exchanger and boiler coatings for enhanced thermal efficiency.

The graphene tape may also be used for encapsulation because graphene is hydrophobic, it blocks water, it is highly electrically and thermally conductive and because it is transparent in visible wavelengths (one layer of graphene only absorbs 2.3%) and even higher transparency for doped graphene in the infrared. It could also be used for electromagnetic shielding. For example, the graphene tape could be used to encapsulate paper documents or paper money with a continuous SLG graphene. This encapsulation would prevent the paper documents from being changed and it would minimize the degradation of the paper since it would prevent from moisture, water and any other contaminants. Since the graphene tape is compatible with the pre-patterning of nanostructures, additional marks and/or shields could also be added to the tape to improve the security of the encapsulation. Following the embodiments of the invention graphene tape can be used to encapsulate other nanomaterials and/or to produce tapes of other nanomaterials, as previously defined, with an encapsulation, for example black phosphorus, to prevent them from degradation when being exposed to oxygen or water environments.

Whilst there has been described in the foregoing description preferred embodiments of the present invention, it will be understood by those skilled in the technology concerned that many variations or modifications in details of design or construction may be made without departing from the present invention.

1. A graphene tape suitable for applying on a target surface, the tape comprising:
(a) a support layer; and
(b) a first nanocomposite layer, the nanocomposite layer comprising a thin film layer and a graphene layer,
wherein the thin film layer is disposed between the support layer and the graphene layer.

2. The graphene tape according to claim 1, wherein the thin film layer is a non-sacrificial thin film layer and is adapted to provide a functionality to the graphene layer.

3. The graphene tape according to claim 1, wherein the thin film layer is a polymer and is any one selected from the group consisting of: polymethyl methacrylate (PMMA), polyvinylidene fluoride (PVDF) and its copolymers, poly(3-hexylthiophene) (P3HT), and polylactide (PLA).

4. The graphene tape according to claim 1, wherein the graphene layer is a matrix of graphene embedded in a thin film.

5. The graphene tape according to claim 1, further comprising a second nanocomposite layer disposed on the support layer on a surface opposite the first nanocomposite layer.

6. The graphene tape according to claim 1, wherein the nanocomposite layer comprises a plurality of alternating thin film layers and graphene layers.

7. The graphene tape according to claim 1, further comprising an adhesive layer disposed between the support layer and the nanocomposite layer, wherein the thin film layer is disposed between the adhesive layer and the graphene layer.

8. The graphene tape according to claim 1, further comprising a first protector layer disposed on the support layer on a surface opposite the nanocomposite layer, and a second protector layer disposed on the nanocomposite layer on a surface opposite the support layer.

9. The graphene tape according to claim 1, wherein the graphene layer is patterned.

10. The graphene tape according to claim 1, wherein the target surface is any one selected from the group comprising: silicon wafers, glass, quartz, mica, polyethylene terephthalate, polyimide foils, and paper.

11. A method of forming a graphene tape, the method comprising:
(a) providing a substrate;
(b) forming a graphene layer on the substrate;
(c) depositing a thin film layer on the graphene layer;
(d) applying a supporting layer on the thin film layer; and
(e) removing the substrate.

12. The method according to claim 11, wherein the thin film layer is a non-sacrificial thin film layer and is adapted to provide a functionality to the graphene layer.

13. The method according to claim 11, further comprising cleaning the graphene layer prior to depositing a thin film layer on the graphene layer.

14. The method according to claim 11, wherein the step of depositing the thin film layer on the graphene layer is any one selected from the group consisting of: bar-coating, spin coating, spray coating, polymer evaporation, Langmuir-Blodgett deposition, dip coating, doctor blade, slot-die coating, film lamination, and direction deposition from melt.

15. The method according to claim 11, wherein the step of applying the supporting layer on the thin film layer is by any one from selected group consisting of: electrostatic transfer, rolling, laminating, hot-pressing, and autoclave processing.

16. The method according to claim 11, wherein the step of removing the substrate is any one selected from the group consisting of: chemical removal, electrostatic transfer, and chemical delamination.

17. The method according to claim 11, wherein the steps (b) and (c) are repeated after step (e).

18. The method according to claim 11, wherein the method further comprises patterning the graphene and thin film layers.

19. The method according to claim 11, wherein the thin film layer is a polymer and is any one selected from the group consisting of: polymethyl methacrylate (PMMA), polyvinylidene fluoride (PVDF) and its copolymers, polymer poly(3-hexylthiophene) (P3HT), and polylactide (PLA).

20. The method according to claim 11, wherein the substrate is a copper metal substrate.
